(19) United States
(12) Patent Application Publication
(10) Pub. No.: US 2008/0157785 A1
(43) Pub. Date: Jul. 3, 2008

(54) Method For Determining the State of a Spatially Extended Body

(75) Inventor: Hermann Koch, Gerhardshofen (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, München (DE)

(21) Appl. No.: 11/913,980

(22) PCT Filed: Apr. 20, 2006
(86) PCT No.: PCT/EP06/61696

§ 371 Date: Nov. 9, 2007

(30) Foreign Application Priority Data
May 9, 2005 (DE) 10 2005 022 180.7

(51) Int. Cl. G01R 31/08

(52) U.S. Cl. 324/613

(57) ABSTRACT

The invention relates to a long body, for example a gas-insulated electric line (1), the condition of which is tested by an electronic signal that is supplied to the body and then received by a receiver unit. The electronic signal has a predefined duration and form. The receiver unit receives signals, evaluates them in terms of duration and/or form and identifies the signals as the supplied signals or discards them as interference signals.

The invention relates to a method for determining the state of a spatially extended body, in which an electronic signal is fed into the body and can be received by a receiving device.

It is known, for example in order to diagnose a corrosion protection coating on pipes, for an electrical signal to be fed into the pipe and for this electrical signal to be detected by means of a receiving device. A signal of greater or lesser strength and/or the form of which has been changed can be received depending on the state of the corrosion protection coating. The state of the corrosion protection coating can then be deduced from the received signals.

In the case of spatially extended bodies, for example long pipelines, it is virtually impossible to prevent superimposition of interference signals. These interference signals make it harder to identify the electrical signal that was fed in.

The object of the invention is to specify a method which allows the state of a spatially extended body to be determined more reliably.

According to the invention, in the case of a method of the type mentioned initially, this is achieved in that the electronic signal has a predetermined time duration and form, in that the receiving device receives signals and evaluates them with respect to their time duration and/or form, and identifies them as a signal which has been fed in or rejects them as an interference signal.

The electronic signal can be clearly identified by the predetermined time duration and the predetermined form. Interference signals can easily be selected and rejected by the receiving device. Evaluation is therefore restricted to the electronic signals of interest. This improves the method accuracy since disturbance variables are excluded from further analyses from the start.

In this case, both analogue signals and digital signals may be used as electrical signals. In this case, the signals may have typical waveforms, such as sinusoidal oscillations at a specific frequency, sawtooth waveforms or specific pulse sequences.

One advantageous refinement of the invention also makes it possible to provide for the electronic signal to be fed in a cyclically repeated form.

Feeding the electronic signal in a cyclically repeated form offers the advantage that a plurality of signal sequences can be detected, thus providing an improved diagnosis capability. For example, this makes it possible to provide for a choice of the most characteristic signals to be made from a plurality of received electronic signals, so that a further improvement in the quality of the method can be achieved even at this stage. Electronic signals which have been identified as electronic signals but have certain interference superimposed on them can therefore be excluded from further analysis. Furthermore, the cyclic repetition of the electronic signal also makes it possible to make use of the repetition cycle as an identification feature, in addition to the time duration and/or the form of the signal.

Furthermore, it is advantageously possible to provide for electronic signals with different time durations and different forms to be fed in.

When the method is used in fields in which the electronic signal is subject to relatively major interference, it is advantageous to feed different electronic signals into the spatially extended body. An additional distinguishing criterion for the receiving device can be provided by changing between different forms of electronic signals. For example, this means that it is also possible to provide for the cyclically repeated transmission of a sequence of different electronic signals with different time durations and different forms. This sequence can then be received by the receiving device and allows a higher identification probability even when subject to relatively major interference. In this case, it is possible to provide for the sequence of different electronic signals to be transmitted in a cyclically repeated form. In this case, it is also possible to provide for the receiving device to continuously detect different forms of electronic signals and, on identification of individual signals, to automatically search for further electronic signals with specific forms and with specific time durations. In addition, the cyclic repetition can in this case be detected automatically by the receiving device. This automatic operation of the receiving device allows it to be used with different transmitting devices. Synchronization and tuning of the transmitting and receiving device need therefore take place only within a certain framework. The receiving device need be able only to additionally receive the signals transmitted from a transmitting device. There is therefore no need for any restriction to a specific frequency band or to a specific form.

It is also possible to advantageously provide for a start and/or end time of the electronic signal to be defined using a counting pulse which is emitted from a satellite in an earth orbit.

There are satellites in earth orbit which transmit different counting pulses which can be received by appropriate apparatuses. These counting pulses can be used to synchronize very accurate timing and counting processes. These counting pulses can be received throughout the world and have an accuracy which is adequate for carrying out the method according to the invention. The electronic signal can therefore be produced very accurately, irrespective of where the transmitting device for the electronic signal is located. In the same way as the transmitting device that is required, the receiving device can also receive the counting pulses from the satellite, and can carry out a synchronization process. The transmitting and receiving device therefore have a time measurement system of the same quality. This prevents measurement errors. The transmitting device for the electronic signal and the receiving device for the electronic signal move within the same time measurement system, with the same error discrepancy.

One exemplary embodiment of the invention will be explained in more detail in the following text and is illustrated schematically in the figures, in which:

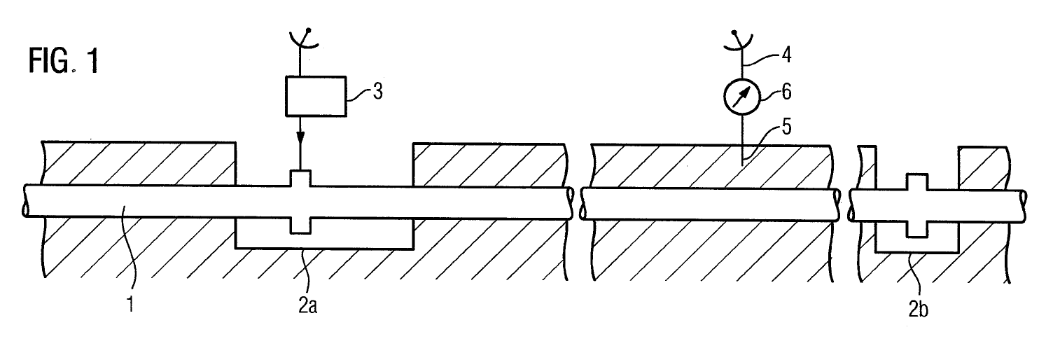

FIG. 1 shows a spatially extended body to be examined, and

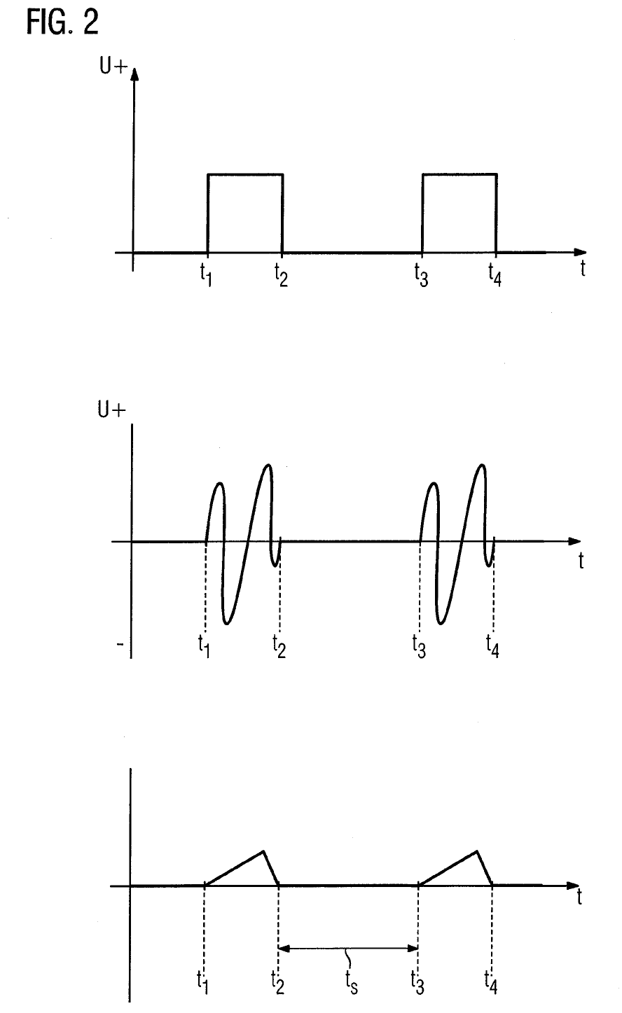

FIG. 2 shows various electronic signals.

FIG. 1 shows a gas-insulated electrical line 1 which acts as a spatially extended body. The gas-insulated electrical line 1 has a tubular outer casing which is provided with a corrosion protection coating. The outer casing surrounds an electrical conductor, which is mounted such that it is electrically insulated. The interior of the outer casing of the gas-insulated electrical line 1 is filled with a pressurized insulating gas. In the example shown in FIG. 1, the gas-insulated electrical line 1 has been laid underground. Alternatively, however, other types of line, for example within a waterway or within a tunnel, are also possible. The outer casing of the gas-insulated electrical line can be accessed through maintenance shafts 2a, 2b. An electronic signal can be fed into the outer casing of the gas-insulated electrical line 1 by means of a transmitting device 3. The outer casing of the gas-insulated electrical line 1 is formed, for example, from an electrically conductive material. The electronic signal that is fed in propagates within the outer casing. A corrosion protection coating located on the outer casing prevents the signal from passing from the casing into the surrounding ground. Only relatively small leakage currents can pass through the corrosion protection coating. If the corrosion protection coating is damaged, this make it possible for the signal to pass through the corrosion coating. In order to detect such faults, a receiving device 4 is, for example, equipped with a probe 5 which can make contact with the ground. The electronic signal can be displayed with greater or lesser strength, depending on the state of the corrosion protection coating, by means of a display instrument 6, for example a potentiometer.

For example, the display instrument 6 could also be made to display vagabond interference signals in the ground. In order to avoid this, the transmitting device 3 has a receiving apparatus for receiving counting pulses from a satellite which is in an earth orbit. The counting pulses can be used to synchronize the electronic signal emitted from the transmitting device 3, that is to say the electronic signal can be started and stopped at exact times. On the one hand, this influences the time duration of the signal, and on the other hand it defines the sequence time between two repetitions, when the signal is repeated cyclically.

In the same way as the transmitting device 3, the receiving device 4 is equipped with a receiving apparatus such as this, so that the receiving device 4 can also be synchronized using the counting pulses from the satellite which is in earth orbit. This ensures that both the transmitting device 3 and the receiving device 4 are operating within the same time system, and that the signal can be transmitted and received with an accuracy, for example, of down to one microsecond. High resolution of the timing of the electronic signals such as this results in reliable identification by the receiving device 4 of the signals which have been fed in by the transmitting device 3.

By way of example, FIG. 2 shows various signal forms. The transmitting device 3 in each case starts to transmit a signal at the time t₁. This signal in each case ends at the time t₂. A so-called sequence time is in each case provided between the time t₂ and the time t₃. Once the sequence time has elapsed, a signal can once again be fed into the casing of the gas-insulated electrical conductor 1. In this case, it is possible to provide for the signals illustrated in the diagrams in FIG. 2 each to be transmitted on their own cyclically and successively, or else for combinations of the various signal sequences to be used. A combination of the various signal forms offers the advantage that a typical cyclically recurring image is produced, which can easily be identified by the receiving device 4. This makes it possible to distinguish between the electronic signal fed in by the transmitting device 3 and interference signals.

1-4. (canceled)

5: A method for determining a condition of a spatially extended body, the method which comprises:
feeding an electronic signal into the body, the electronic signal having a predetermined time duration and form; and
connecting a receiving device to receive the signals from the body, and evaluating the signals with the receiving device with respect to a time duration and/or a form, and identifying the signals with the receiving device as a signal that has been fed in the feeding step or rejecting the signals as an interference signal.

6: The method according to claim 5, which comprises feeding in the electronic signal in a cyclically repeated form.

7: The method according to claim 5, which comprises feeding in electronic signals with different time durations and different forms.

8: The method according to claim 5, which comprises defining a start time and/or an end time of the electronic signal using a counting pulse emitted from a satellite in an earth orbit.
